(19) United States
(12) Patent Application Publication
(10) Pub. No.: US 2020/0160933 A1
(43) Pub. Date: May 21, 2020

(54) NON-VOLATILE MEMORY AND TESTING METHOD WITH YIELD IMPROVEMENT

(71) Applicant: eMemory Technology Inc., Hsin-Chu (TW)

(72) Inventor: Wein-Town SUN, Hsinchu County (TW)

(21) Appl. No.: 16/564,010

(22) Filed: Sep. 9, 2019

Related U.S. Application Data
(60) Provisional application No. 62/768,099, filed on Nov. 16, 2018.

(30) Foreign Application Priority Data
Jul. 18, 2019 (TW) 108125501

(51) Int. Cl. G11C 29/50; G11C 16/14; G11C 16/26; G11C 16/10; G11C 16/34; G11C 16/08; G11C 16/04

(52) U.S. Cl. CPC G11C 29/50004; G11C 16/14; G11C 16/26; G11C 16/10; G11C 2029/5006; G11C 16/3459; G11C 16/08; G11C 16/0408; G11C 2029/5004; G11C 16/3445

(57) ABSTRACT

A testing method is provided for testing a memory die of a non-volatile memory. The testing method includes the following steps. Firstly, an erase action is performed on plural memory cells of the memory die. Then, a stress is applied to the plural memory cells of the memory die. Then, a read action is performed on the plural memory cells of the memory die to have the plural memory cells generate plural off currents, and a maximum off current is acquired from the plural off currents. Then, a specified test criterion set is selected from plural test criterion sets according to the maximum off current, and the memory die is tested according to plural test currents or plural test voltages of the specified test criterion set.

This application claims the benefit of U.S. provisional application Ser. No. 62/768,099, filed Nov. 16, 2018, and Taiwan Patent Application No. 108125501, filed Jul. 18, 2019, the subject matters of which are incorporated herein by reference.

### FIELD OF THE INVENTION

The present invention relates to a non-volatile memory and a testing method with yield improvement, and more particularly to a a multi-time programmable (MTP) non-volatile memory and a method of testing the MTP non-volatile memory by acquiring a judgement current, a reference current or a judgement voltage from the non-volatile memory.

### BACKGROUND OF THE INVENTION

FIG. 1 is a schematic circuit diagram of a conventional MTP non-volatile memory. The MTP non-volatile memory comprises plural memory cells, which are arranged in an array. For succinctness, two memory cells 100 and 102 in a column are shown in FIG. 1. The memory cells 100 and 102 are connected with the same bit line BL. The structures of the memory cells 100 and 102 are identical. Moreover, the memory cell 100 is connected with a word line WLx, and the memory cell 102 is connected with a word line WLx+1. The memory cell 100 comprises a select transistor Ms, a floating gate transistor Mf and erase gate element Ce. For example, the select transistor Ms and the floating gate transistor Mf are p-type transistors. The select transistor Ms and the floating gate transistor Mf are constructed in an n-well region NW. Moreover, a body terminal of the select transistor Ms and a body terminal of the floating gate transistor Mf are connected with the n-well region NW.

The gate terminal of the select transistor Ms is connected with the word line WLx. A first terminal of the select transistor Ms is connected with a source SL. A second terminal of the select transistor Ms is connected with a first terminal of the floating gate transistor Mf. A second terminal of the floating gate transistor Mf is connected with the bit line BL. The erase gate element Ce may be considered as a capacitor. A first terminal of the erase gate element Ce is connected with a floating gate FG of the floating gate transistor Mf. A second terminal of the erase gate element Ce is connected with an erase line EL.

Generally, the selected memory cell is determined after the corresponding word line is activated. Moreover, a program action, an erase action or a read action may be performed on the selected memory cell. For example, if the word line WLx is activated, the memory cell 100 is the selected memory cell. Since the other word lines are not activated, the other memory cells connected with the bit line BL are non-selected memory cells.

For performing the program action, about a half of a program voltage (Vpp/2) is provided to the word line WLx and the erase line EL, the program voltage Vpp is provided to the source line SL and the n-well region NW, and a ground voltage (0V) is provided to the bit line BL. Since electrons are injected into the floating gate FG through a channel region of the floating gate transistor Mf, the selected memory cell 100 is in a program state. For example, the magnitude of the program voltage Vpp is 8V. In the non-selected memory cell, the bit line receives the program voltage Vpp, and the bit line is inactivated. In addition, the voltages provided to the erase line EL, the source line SL, the n-well region NW and the bit line BL of the non-selected memory cell are identical to those of the selected memory cell.

For performing the erase action, the ground voltage (0V) is provided to the source line SL, the bit line BL and the n-well region NW, and an erase voltage Vee is provided to the erase line EL. Since the electrons in the floating gate FG is transferred to the erase line EL through the erase gate element Ce and ejected from the floating gate FG, the selected memory cell 100 is in an erase state. For example, the magnitude of the erase voltage Vee is 16V.

For performing a read action, a read voltage Vr is provided to the source line SL and the n-well region NW, and the ground voltage (0V) is provided to the bit line BL. The magnitude of a read current generated by the floating gate transistor Mf and transmitted to the bit line BL is determined according to the storage state of the selected memory cell 100. Moreover, the non-selected memory cells connected with the bit line BL do not generate the read current. For example, the magnitude of the read voltage Vr is 2.5V.

For example, while the read action is performed on the selected memory cell 100 in the program state, the floating gate transistor Mf is turned on because electrons are stored in the floating gate FG. Consequently, the magnitude of the read current generated by the selected memory cell 100 is higher. Whereas, while the read action is performed on the selected memory cell 100 in the erase state, the floating gate transistor Mf is turned off because no electrons are stored in the floating gate FG. Consequently, the magnitude of the read current generated by the selected memory cell 100 is very low. In other words, the read current generated by the memory cell in the program state may be referred as an on current Ion, and the read current generated by the memory cell in the erase state may be referred as an off state Ioff.

Moreover, the MTP non-volatile memory further comprises a sensing circuit (not shown). The sensing circuit is connected with the bit line BL. According to the magnitude of the read current, the sensing circuit can judge the storage state of the selected memory cell 100.

FIG. 2 is a schematic circuit diagram of another conventional MTP non-volatile memory. The MTP non-volatile memory comprises plural memory cells, which are arranged in an array. For succinctness, two memory cells 200 and 202 in a column are shown in FIG. 2. The memory cells 200 and 202 are connected with the same bit line BL. The structures of the memory cells 200 and 202 are identical. Moreover, the memory cell 200 is connected with a word line WLy, and the memory cell 202 is connected with a word line WLy+1. The memory cell 200 comprises a select transistor Ms and a storage transistor Mt. For example, the select transistor Ms and the storage transistor Mt are p-type transistors. The select transistor Ms and the storage transistor Mt are constructed in an n-well region NW. Moreover, a body terminal of the select transistor Ms and a body terminal of the storage transistor Mt are connected with the n-well region NW.

The gate terminal of the select transistor Ms is connected with the word line WLy. A first terminal of the select transistor Ms is connected with a source SL. A second terminal of the select transistor Ms is connected with a first terminal of the storage transistor Mt. A second terminal of the storage transistor Mt is connected with the bit line BL. The control gate of the storage transistor Mt is connected with a control line CL. Moreover, a storage dielectric layer Sd is arranged between the control gate and a channel region of the storage transistor Mt for storing electrons. For example, the storage dielectric layer Sd is made of silicon nitride (Si₃N₄).

Similarly, the selected memory cell is determined after the corresponding word line is activated. Moreover, a program action, an erase action or a read action may be performed on the selected memory cell. For example, if the voltage in the range between 0V and 1V is provided to the word line WLy and the word line WLy is activated, the memory cell 200 is the selected memory cell. Since the other word lines receive the voltage Vpp and are not activated, the other memory cells connected with the bit line BL are non-selected memory cells.

For performing the program action, the program voltage Vpp (e.g., 5.2V) is provided to the control line CL, the source line SL and the n-well region NW, and a ground voltage (0V) is provided to the bit line BL. Since electrons are injected into the storage dielectric layer Sd through a channel region of the storage transistor Mt, the selected memory cell 200 is in a program state.

For performing the erase action, a positive voltage (e.g., 6V) is provided to the source line SL, the bit line BL and the n-well region NW, an a negative erase voltage Vee (e.g., −6V) is provided to the control line CL. Since the electrons in the storage dielectric layer Sd is ejected to the channel region of the storage transistor Mt, the selected memory cell 200 is in an erase state.

For performing a read action, another positive voltage (e.g., 2.2V) is provided to the source line SL and the n-well region NW, the ground voltage (0V) is provided to the bit line BL, and a read voltage Vr (e.g., 2.4V) is provided to the control line CL. The magnitude of a read current generated by the storage transistor Mt and transmitted to the bit line BL is determined according to the storage state of the selected memory cell 200. Moreover, the non-selected memory cells connected with the bit line BL do not generate the read current.

For example, while the read action is performed on the selected memory cell 200 in the program state, the storage transistor Mt is turned on because electrons are stored in the storage dielectric layer Sd. Consequently, the magnitude of the read current generated by the selected memory cell 200 is higher. Whereas, while the read action is performed on the selected memory cell 200 in the erase state, the storage transistor Mt is turned off because no electrons are stored in the storage dielectric layer Sd. Consequently, the magnitude of the read current generated by the selected memory cell 200 is very low. In other words, the read current generated by the memory cell in the program state may be referred as an on current Ion, and the read current generated by the memory cell in the erase state may be referred as an off state Ioff.

Moreover, the MTP non-volatile memory further comprises a sensing circuit (not shown). The sensing circuit is connected with the bit line BL. According to the magnitude of the read current, the sensing circuit can judge the storage state of the selected memory cell 200.

Due to the process variation of the MTP non-volatile memory, the on currents Ion generated by all memory cells of the MTP non-volatile memory in the program state are usually different. Similarly, the off currents Ioff generated by all memory cells of the MTP non-volatile memory in the erase state are usually different.

FIG. 3A schematically illustrates a read current distribution curve of all memory cell in the conventional MTP non-volatile memory. When all memory cells in a memory die of the MTP non-volatile memory are in the program state (i.e., a PGM state), the on currents Ion are distributed as the distribution curve of FIG. 3A. As shown in FIG. 3A, the number of the memory cells corresponding to the on current Ion of 15 μA is the largest.

Similarly, when the memory cells are in the erase state (i.e., an ERS state), the off currents Ioff are distributed as the distribution curve of FIG. 3A. Moreover, all of the off currents Ioff are lower than 1 μA.

Generally, all memory cells in the memory die of the MTP non-volatile memory have different characteristics. Consequently, after the memory die is fabricated, it is necessary to test all memory cells.

For example, a reference current Iref (e.g., 5 μA) is defined. Then, a program action is performed on the memory die. Consequently, all memory cells in the memory die are in the program state. Then, the on currents Ion of the memory cells are read. If the on current Ion generated by any memory cell in the program state is lower than the reference current Iref, the memory die is considered as a bad die.

Moreover, after an erase action is performed on the memory die, all memory cells in the memory die are in the erase state. Then, the off currents Ioff of the memory cells are read. If the off current Ioff of any memory cell in the erase state is higher than the reference current Iref, the memory die is considered as a bad die.

FIG. 3B schematically illustrates a threshold voltage distribution curve of all memory cell in the conventional MTP non-volatile memory. When all memory cells in a memory die of the MTP non-volatile memory are in the program state (i.e., the PGM state), the threshold voltages of the storage transistors or the floating gate transistors in all memory cells are distributed as the distribution curve of FIG. 3B. As shown in FIG. 3B, the number of the memory cells corresponding to the threshold voltage of 5.0V is the largest. Similarly, when the memory cells are in the erase state (i.e., the ERS state), the threshold voltages of the storage transistors or the floating gate transistors in all memory cells are distributed as the distribution curve of FIG. 3B. Moreover, all of the threshold voltages are lower than 1.2V.

For example, a reference voltage Vref (e.g., 2.0V) is defined. Then, a program action is performed on the memory die. Consequently, all memory cells in the memory die are in the program state. Then, the threshold voltages of the memory cells are read. If the threshold voltage of any memory cell in the program state is lower than the reference voltage Vref, the memory die is considered as a bad die.

Moreover, after an erase action is performed on the memory die, all memory cells in the memory die are in the erase state. Then, the threshold voltages of the memory cells are read. If the threshold voltage of any memory cell in the erase state is higher than the reference voltage Vref, the memory die is considered as a bad die.

If the memory die is judged as the bad die, the memory die can be sold. If all memory cells in the memory die pass the above testing process, the memory die is judged as the good die. The good die can be sold to the market.

### SUMMARY OF THE INVENTION

An embodiment of the present invention provides a testing method for testing a memory die of a non-volatile memory. The testing method includes the following steps. Firstly, an erase action is performed on plural memory cells of the memory die. Then, a stress is applied to the plural memory cells of the memory die. Then, a read action is performed on the plural memory cells of the memory die to have the plural memory cells generate plural off currents, and a maximum off current is acquired from the plural off currents. Then, a specified test criterion set is selected from plural test criterion sets according to the maximum off current, and the memory die is tested according to plural test currents or plural test voltages of the specified test criterion set.

Another embodiment of the present invention provides a testing method for testing a memory die of a non-volatile memory. The testing method includes the following steps. Firstly, a program action is performed on plural memory cells of the memory die. Then, a read action is performed on the plural memory cells of the memory die to have the plural memory cells generate plural on currents, and a minimum on current is acquired from the plural on currents. Then, a specified test criterion set is selected from plural test criterion sets according to the minimum on current, and the memory die is tested according to plural test currents or plural test voltages of the specified test criterion set.

A further embodiment of the present invention provides a non-volatile memory die. The non-volatile memory die includes a word line driver, a memory cell array, a sense amplifier, a storage element and a look-up table. The memory cell array is connected with the word line driver, and includes plural memory cells. The sense amplifier is connected with the memory cell array. When a read action is performed and plural read currents are generated by the plural memory cells, the sense amplifier determines a maximum off current or a minimum on current from the plural read currents. The storage element is connected with the sense amplifier. The maximum off current or the minimum on current is stored in the storage element. The look-up table stores plural test criterion sets. When a testing process is performed, the maximum off current or the minimum on current is transmitted from the storage element to the look-up table, and a specified test criterion set is selected from the plural test criterion set according to an operation mode control signal. Moreover, plural test current or plural test voltages of the specified test criterion set are transmitted from the look-up table to the sense amplified, and the plural memory cells of the memory cell array are tested according to the plural test current or plural test voltages of the specified test criterion set.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 (prior art) is a schematic circuit diagram illustrating a conventional MTP non-volatile memory;

FIG. 2 (prior art) is a schematic circuit diagram of another conventional MTP non-volatile memory;

FIG. 3A (prior art) schematically illustrates a read current distribution curve in all memory cell of the conventional MTP non-volatile memory;

FIG. 3B (prior art) schematically illustrates a threshold voltage distribution curve of all memory cell in the conventional MTP non-volatile memory;

FIG. 4 schematically illustrates the shifts of a read current distribution curve of the MTP non-volatile memory;

FIG. 5A is a flowchart illustrating a testing method of a MTP non-volatile memory according to a first embodiment of the present invention;

FIG. 5B is a lookup table about several test criterion sets;

FIG. 5C is schematically illustrates the relationships between the read current distribution curves of the MTP non-volatile memory and associated currents of the specified test criterion set of the look-up table;

FIG. 6A is a flowchart illustrating a testing method of a MTP non-volatile memory according to a second embodiment of the present invention;

FIG. 6B is a lookup table about several test criterion sets;

FIG. 6C is schematically illustrates the relationships between the read current distribution curves of the MTP non-volatile memory and associated voltages of the specified test criterion set of the look-up table;

FIG. 7A is a flowchart illustrating a testing method of a MTP non-volatile memory according to a second embodiment of the present invention;

FIG. 7B is a lookup table about several test criterion sets;

FIG. 7C is schematically illustrates the relationships between the read current distribution curves of the MTP non-volatile memory and associated currents of the specified test criterion set of the look-up table; and

FIG. 8 schematically illustrates the architecture of a non-volatile memory die using the testing method of the present invention.

### DETAILED DESCRIPTION OF PREFERRED EMBODIMENTS

When the memory cell is in the program state, the extent of turning on the memory cell is determined according to the amount of electrons stored in the floating gate or the storage dielectric layer. If the amount of electrons stored in the floating gate or the storage dielectric layer is higher, the floating gate transistor or the storage transistor is in a stronger turn-on status. Under this circumstance, the on current Ion generated by the memory cell is higher. Whereas, if the amount of electrons stored in the floating gate or the storage dielectric layer is higher, the floating gate transistor or the storage transistor is in a weaker turn-on status. Under this circumstance, the on current Ion generated by the memory cell is lower.

Similarly, when the memory cell is in the erase state, the extent of turning off the memory cell is determined according to the amount of electrons stored in the floating gate or the storage dielectric layer. If the amount of electrons stored in the floating gate or the storage dielectric layer is very low (or nearly zero), the floating gate transistor or the storage transistor is in a stronger turn-off status. Under this circumstance, the off current Ioff generated by the memory cell is lower. Whereas, if the amount of electrons stored in the floating gate or the storage dielectric layer is higher, the floating gate transistor or the storage transistor is in a weaker turn-off status. Under this circumstance, the off current Ioff generated by the memory cell is higher.

Moreover, if the memory cell in the erase state is suffered from voltage stress, a smaller portion of electrons are injected into the floating gate or the storage dielectric layer. Consequently, the floating gate transistor or the storage transistor is in the weaker turn-off status. Under this circumstance, the off current Ioff generated by the memory cell is increased.

Moreover, if the memory cell in the erase state undergoes a soft program action, electrons are also injected into the floating gate transistor or the storage transistor. Consequently, the floating gate transistor or the storage transistor is in the weaker turn-off status. Under this circumstance, the off current Ioff generated by the memory cell is increased.

Similarly, if the memory cell in the program state undergoes a soft erase action, a smaller portion of electrons are injected into the floating gate or the storage dielectric layer. Under this circumstance, the on current Ion generated by the memory cell is decreased.

Generally, when the floating gate transistor or the storage transistor is in the stronger turn-on status, the amount of electrons stored in the floating gate or the storage dielectric layer is higher. When the floating gate transistor or the storage transistor is in the stronger turn-off status, the amount of electrons stored in the floating gate or the storage dielectric layer is very low. Moreover, the amount of electrons stored in the floating gate or the storage dielectric layer of the floating gate transistor or the storage transistor in the weaker turn-on status is higher than the amount of electrons stored in the floating gate or the storage dielectric layer of the floating gate transistor or the storage transistor in the weaker turn-off status.

Generally, due to the column stress, the soft program action or the soft erase action, electrons may be injected into or ejected from the floating gate or the storage dielectric layer.

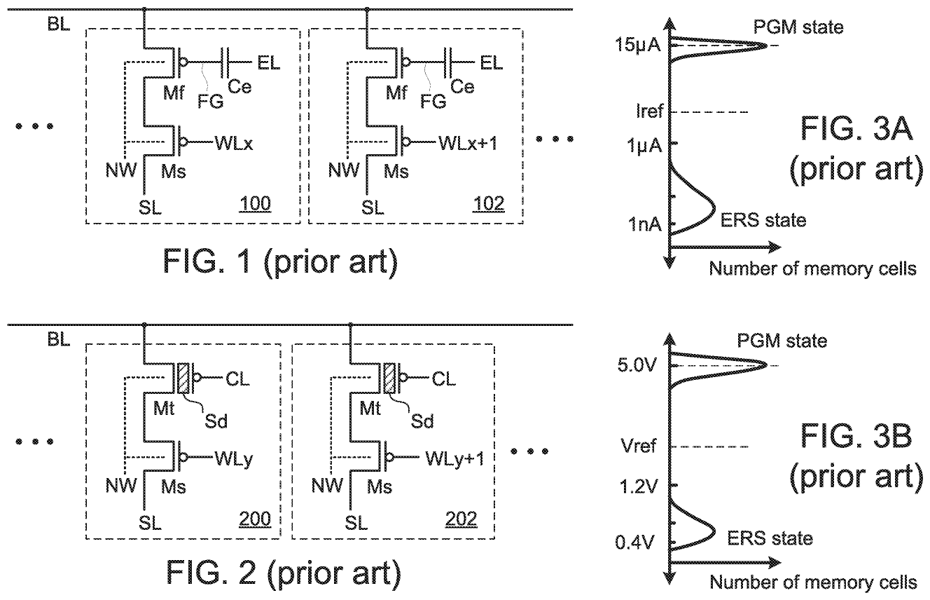

For example, the MTP non-volatile memory comprises as shown in FIG. 1 or FIG. 2 comprises 64 memory cells in a row. These memory cells are connected with the same bit line BL.

For changing the 64 memory cells from the erase state to the program state, it is necessary to perform 64 program actions. That is, these 64 memory cells are served as the selected memory cells sequentially. Whenever the program action is performed, the selected memory cell is changed from the erase state to the program state but the non-selected memory cells are kept unchanged.

As mentioned above, only the selected memory cell is changed from the erase state to the program state while the program action is performed. However, while the program action is performed on the selected memory cell, the other floating gate transistors or storage transistors in the erase state are also suffered from the voltage stress. Consequently, a smaller portion of electrons are injected into the floating gates or the storage dielectric layers. In other words, when the last program action is performed on the selected memory cell, the selected memory cell has been suffered from the voltage stress for 63 times. Assuming that the time period of performing one program action is 50 μs, the selected memory cell undergoing the last program action has been suffered from the voltage stress for 3.15 ms (=50μ×63). That is, the duration of the column stress is 3.15 ms.

Similarly, in case that the MTP non-volatile memory comprises 128 memory cells in a row and these memory cells are connected with the same bit line BL, the selected memory cell undergoing the last program action has been suffered from the voltage stress for 6.35 ms (=50μ×127). As the number of memory cells in a row increases, the column stress increases. Since more electrons are injected into the floating gate, the off current Ioff increases.

Moreover, an erase verification (EV) action is optionally performed on the memory cells to confirm whether the memory cells are changed to the erase state successfully. The erase verification action is used to judge whether the erase action is completed according to the magnitude of the off currents Ioff of the memory cells. During the erase verification action, the magnitude of the off current Ioff lower than a first threshold current indicates that the erase action of the memory cell is completed. If the magnitude of the off current Ioff is not lower than the first threshold current, the erase action is continuously performed until the magnitude of the off current Ioff is lower than the first threshold current.

After the erase action containing the erase verification action is completed, the amount of electrons stored in the floating gate or the storage dielectric layer is very low (or nearly zero). Since the floating gate transistor or the storage transistor is in the stronger turn-off status, the off current Ioff generated by the memory cell decreases. However, in the future, the memory cell in this erase state may be suffered from a problem. For example, the memory cell in this erase state is not easily programmed. Consequently, the memory cell in the erase state may undergo the soft program action after the erase action is completed.

After the erase action on the memory cell is just done, the soft program action is performed for a short time to inject a small amount of electrons into the floating gate or the storage dielectric layer. Consequently, the floating gate or the storage dielectric layer is changed from the stronger turn-off status to the weaker turn-off status. Under this circumstance, the off current Ioff increases.

Moreover, a program verification (PV) action is optionally performed on the memory cells to confirm whether the memory cells are changed to the program state successfully. The program verification action is used to judge whether the erase action is completed according to the magnitude of the on currents Ion of the memory cells. During the program verification action, the magnitude of the on current Ion higher than a second threshold current indicates that the program action of the memory cell is completed. If the magnitude of the on current Ion is not higher than the second threshold current, the program action is continuously performed until the magnitude of the on current Ion is higher than the second threshold current.

After the program action containing the program verification action is completed, the amount of electrons stored in the floating gate or the storage dielectric layer is larger. Since the floating gate transistor or the storage transistor is in the stronger turn-on status, the on current Ion generated by the memory cell increases. However, in the future, the memory cell in this program state may be suffered from a problem. For example, the memory cell in this program state is not easily erased. Consequently, the memory cell in the program state may undergo the soft program action after the program action is completed.

After the program action on the memory cell is just done, the soft erase action is performed for a short time to eject a small amount of electrons from the floating gate or the storage dielectric layer. Consequently, the floating gate or the storage dielectric layer is changed from the stronger turn-on status to the weaker turn-on status. Under this circumstance, the on current Ion decreases.

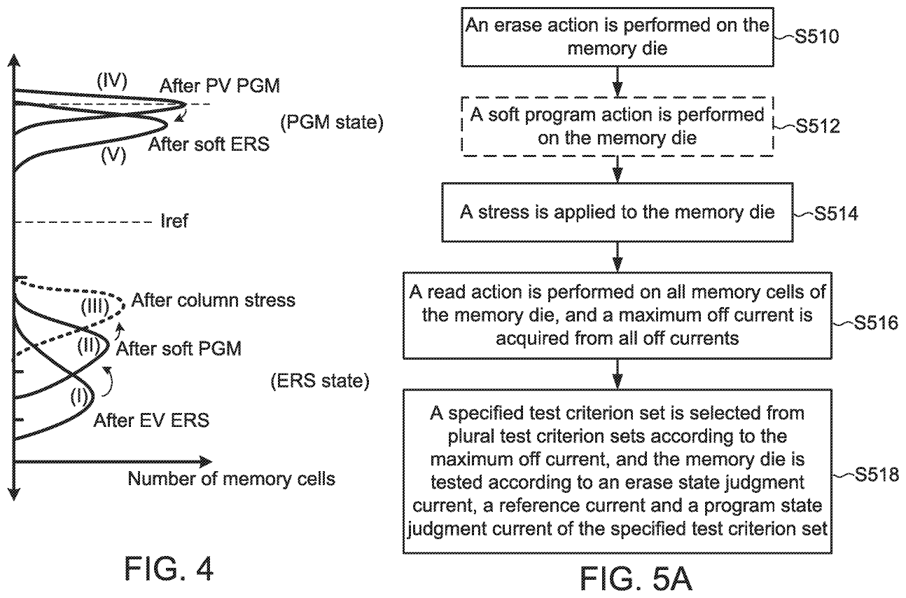

FIG. 4 schematically illustrates the shifts of a read current distribution curve of the MTP non-volatile memory. After the erase action containing the erase verification action is performed on the memory die and completed, the memory cell is in the stronger turn-off status. The distribution of the read current is shown in the curve (I) (After EV ERS). After the soft program action on the memory die is completed, the memory cell is in the weaker turn-off status. The distribution of the read current is shown in the curve (II) (After soft PGM). After memory die is suffered from the column stress, the memory cell is in the weaker turn-off status. The distribution of the read current is shown in the curve (III) (After column stress).

After the program action containing the program verification action is performed on the memory die and completed, the memory cell is in the stronger turn-on status. The distribution of the read current is shown in the curve (IV) (After PV PGM). After the soft erase action is performed on the memory die, the memory cell is in the weaker turn-on status. The distribution of the read current is shown in the curve (V) (After soft ERS).

According to the characteristics of the MTP non-volatile memory, the present invention provides a testing method of the MTP non-volatile memory.

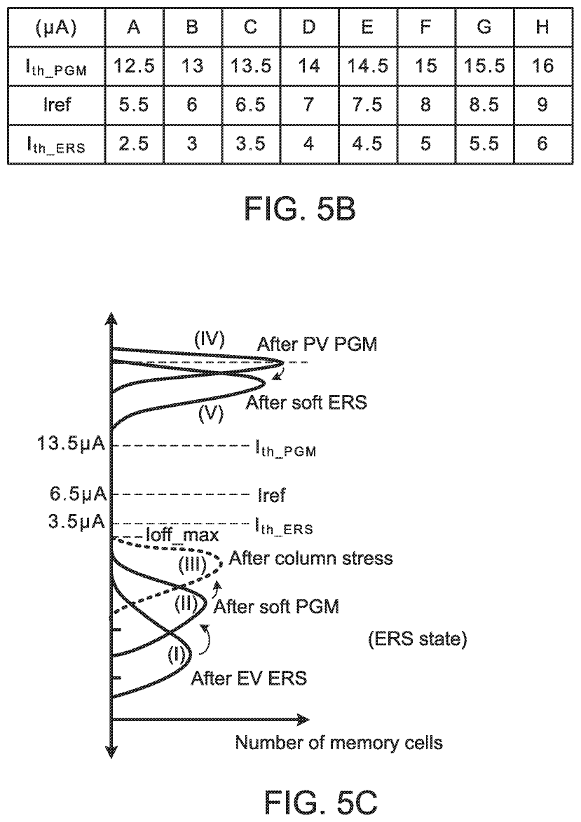

FIG. 5A is a flowchart illustrating a testing method of a MTP non-volatile memory according to a first embodiment of the present invention. FIG. 5B is a lookup table about several test criterion sets. FIG. 5C is schematically illustrates the relationships between the read current distribution curves of the MTP non-volatile memory and associated currents of the specified test criterion set of the look-up table. After the memory die is fabricated, it is necessary to perform plural testing processes for testing all memory cells.

Firstly, an erase action is performed on the memory die (Step S510). In this embodiment, the erase action is performed on all memory cells, or the erase action containing the erase verification action is performed on all memory cells.

Optionally, a soft program action is performed on the memory die (Step S512). After the erase action is completed, all memory dies are in the erase state. Consequently, the step S512 is optionally performed. That is, in some embodiments, the soft program action is not performed.

Then, a stress is applied to the memory die (Step S514). That is, the stress is applied to the memory cells of the memory die. For example, the memory die comprises 64 memory cells in a row. These memory cells are connected with the same bit line BL. In an embodiment, a voltage stress is applied to all memory cells, and the duration of the voltage stress is 3.15 ms (=50μ×63). Alternatively, a heat stress is applied to the all memory cells.

For example, the memory die is placed in a high temperature environment (e.g., 60° C.) for a specified time period (e.g., 24 hours).

Then, a read action is performed on all memory cells of the memory die, and a maximum off current is acquired from all off currents (Step S516). For performing the read action, a normal read voltage (e.g., 2.5V) is provided to all memory cells. Consequently, all memory cells generate the corresponding off currents Ioff. Then, the maximum off current is acquired from all off currents.

In another embodiment, a test read voltage with a higher voltage value (e.g., 3.2V) is provided to all memory cells when the read action is performed. Consequently, all memory cells generate the corresponding off currents Ioff. Then, the maximum off current is acquired from all off currents.

Then, a specified test criterion set is selected from plural test criterion sets according to the maximum off current, and the memory die is tested according to an erase state judgment current, a reference current and a program state judgment current of the specified test criterion set (Step S518). The erase state judgment current, the reference current and the program state judgment current may be considered as test currents for testing the memory die.

As shown in FIG. 5B, the look-up table contains 8 test criterion sets A-H. Each of the test criterion sets A-H contains an erase state judgment current I_{th_ERS}, a reference current Iref and a program state judgment current I_{th_PGM}.

As shown in FIG. 5C, the maximum off current Ioff_max is 3.2 μA. According to the look-up table, the erase state judgment current I_{th_ERS} higher than the maximum off current and the closest to the maximum off current is 3.5 μA.

Since the erase state judgment current I_{th_ERS} of 3.5 μA is included in the test criterion set C, the test criterion set C is the specified test criterion set. Then, the memory die is tested according to the program state judgment current I_{th_PGM} (13.5 μA), the reference current Iref (6.5 μA) and the erase state judgment current I_{th_ERS} (3.5 μA) of the test criterion set C.

After a program action is performed on the memory die, all memory cells in the memory die are in the program state. Then, the on currents Ion of all memory cells are read. If the on current Ion generated by any memory cell in the program state is lower than the program state judgment current I_{th_PGM}, the memory die is considered as a bad die. Whereas, if the on currents Ion of all memory cells are higher than the program state judgment current I_{th_PGM}, the memory die passes the test.

After an erase action is performed on the memory die, all memory cells in the memory die are in the erase state. Then, the off currents Ioff of all memory cells are read. If the off current Ioff generated by any memory cell in the erase state is higher than the erase state judgment current I_{th_ERS}, the memory die is considered as a bad die. Whereas, if the off currents Ioff of all memory cells are lower than the erase state judgment current I_{th_ERS}, the memory die passes the test.

In some situations, the erase operation and the program operation are performed simultaneously. Consequently, the memory cells in a first portion of the memory die are in the erase state, and the memory cells in a second portion of the memory die are in the program state. If the on current Ion generated by any memory cell in the program state is lower than the program state judgment current I_{th_PGM}, the memory die is considered as a bad die. If the off current Ioff generated by any memory cell in the erase state is higher than the erase state judgment current I_{th_ERS}, the memory die is also considered as a bad die.

If all memory cells in the memory die pass the above testing process, the memory die is judged as the good die. The good die can be sold to the market.

In the above testing process, the program state or the erase state of the memory cells is judged according to the reference current Iref. The method of judging the states of the memory cells according to the reference current Iref is not redundantly described herein.

Moreover, the values of the erase state judgment current I_{th_ERS}, the reference current Iref and the program state judgment current I_{th_PGM} used in the testing process may be recorded in the tested memory die. For example, these values are recorded in an antifuse memory of the memory die or a fuse/NVM block of the memory die. After the tested memory die is judged as the good die and sold to the customer, the customer can judge whether the memory cells are in the program state or the erase state according to the reference current Iref recorded in the memory die.

In the above embodiment, each test criterion set contains the erase state judgment current I_{th_ERS}, the reference current Iref and the program state judgment current I_{th_PGM}. It is noted that the contents of the test criterion set are not restricted. For example, in some other embodiments, the test criterion set contains various voltages for testing the memory die.

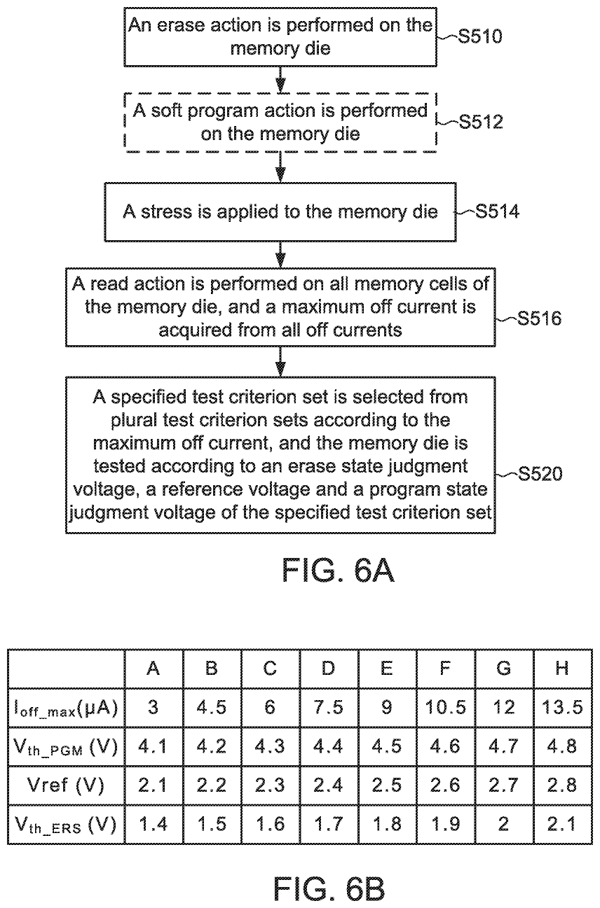

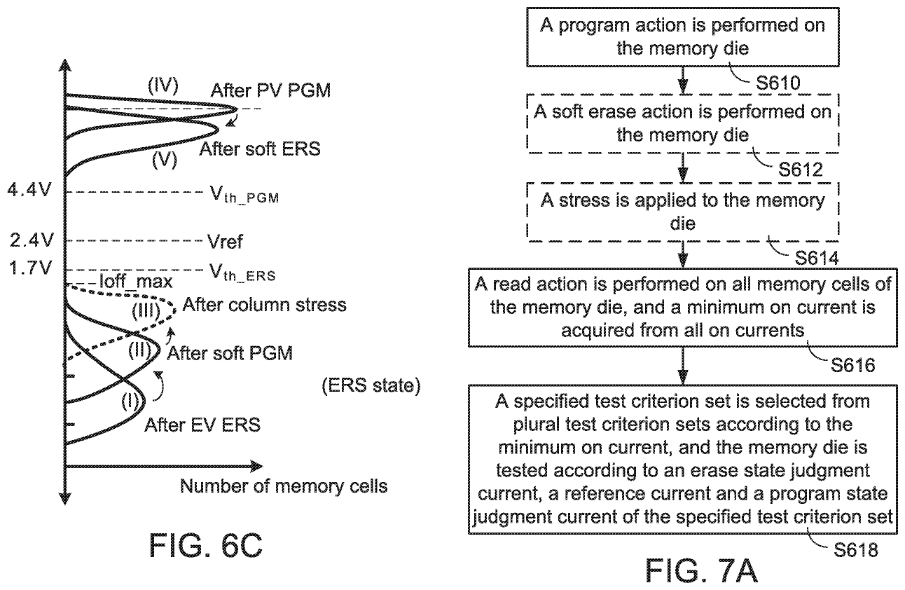

FIG. 6A is a flowchart illustrating a testing method of a MTP non-volatile memory according to a second embodiment of the present invention. FIG. 6B is a lookup table about several test criterion sets. FIG. 6C is schematically illustrates the relationships between the read current distribution curves of the MTP non-volatile memory and associated voltages of the specified test criterion set of the look-up table.

The step S518 of the testing method of the first embodiment is replaced with the step S520 of the testing method of this embodiment. After the step S516, a maximum off current is acquired from all off currents. Then, a specified test criterion set is selected from plural test criterion sets according to the maximum off current, and the memory die is tested according to an erase state judgment voltage, a reference voltage and a program state judgment voltage of the specified test criterion set (Step S520). The erase state judgment voltage, the reference voltage and the program state judgment voltage may be considered as test currents for testing the memory die.

As shown in FIG. 6B, the look-up table contains 8 test criterion sets A-H. Each of the test criterion sets A-H contains the maximum off current Ioff_max, an erase state judgment voltage V_{th_ERS}, a reference voltage Vref and a program state judgment voltage V_{th_PGM}.

As shown in FIG. 6C, the maximum off current Ioff_max is 7.2 μA. The maximum off current Ioff_max in the look-up table and the closest to the maximum off current is 7.5 μA. Since the maximum off current Ioff_max of 7.5 μA is included in the test criterion set D, the test criterion set D is the specified test criterion set. Then, the memory die is tested according to the program state judgment voltage V_{th_PGM} (4.4V), the reference voltage Vref (2.4V) and the erase state judgment voltage V_{th_ERS} (1.7V) of the test criterion set D.

After a program action is performed on the memory die, all memory cells in the memory die are in the program state. Then, the threshold voltages of all memory cells are read. If the threshold voltage of any memory cell in the program state is lower than the program state judgment voltage V_{th_PGM}, the memory die is considered as a bad die. Whereas, if the threshold voltages of all memory cells are higher than the program state judgment voltage V_{th_PGM}, the memory die passes the test. In this embodiment, the threshold voltage of the memory cell denotes the threshold voltage of the storage transistor or the floating gate transistor of the memory cell.

After an erase action is performed on the memory die, all memory cells in the memory die are in the erase state. Then, the threshold voltages of all memory cells are read. If the threshold voltage of any memory cell in the erase state is higher than the erase state judgment voltage V_{th_ERS}, the memory die is considered as a bad die. Whereas, if the threshold voltages of all memory cells are lower than the erase state judgment voltage V_{th_ERS}, the memory die passes the test.

In some situations, the erase operation and the program operation are performed simultaneously. Consequently, the memory cells in a first portion of the memory die are in the erase state, and the memory cells in a second portion of the memory die are in the program state. If the threshold voltage of any memory cell in the program state is lower than the program state judgment voltage V_{th_PGM,} the memory die is considered as a bad die. If the threshold voltage of any memory cell in the erase state is higher than the erase state judgment voltage V_{th_ERS}, the memory die is also considered as a bad die.

If all memory cells in the memory die pass the above testing process, the memory die is judged as the good die. The good die can be sold to the market

In the above testing process, the program state or the erase state of the memory cells is judged according to the reference voltage Vref. The method of judging the states of the memory cells according to the reference voltage Vref is not redundantly described herein.

Moreover, the values of the erase state judgment voltage V_{th_ERS}, the reference voltage Vref and the program state judgment voltage V_{th_PGM} used in the testing process may be recorded in the tested memory die. For example, these values are recorded in an antifuse memory of the memory die or a fuse/NVM block of the memory die. After the tested memory die is judged as the good die and sold to the customer, the customer can judge whether the memory cells are in the program state or the erase state according to the reference voltage Vref recorded in the memory die.

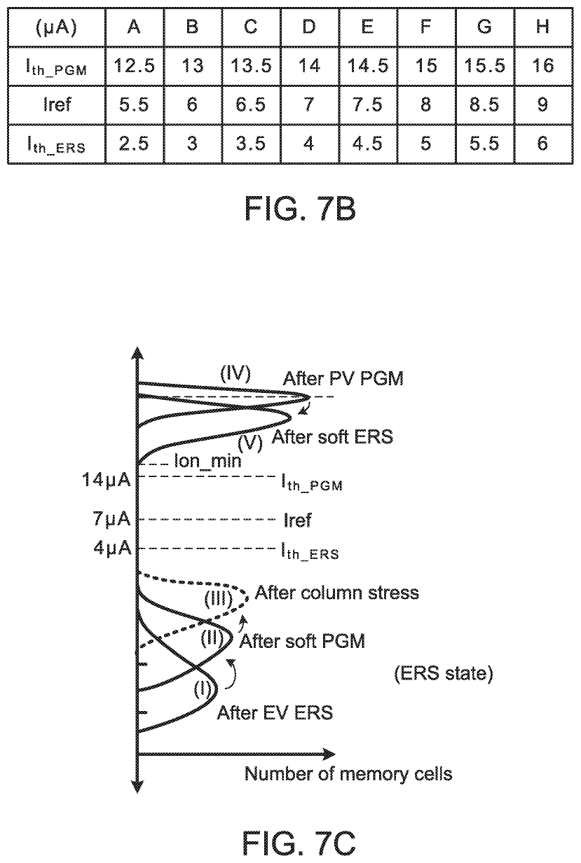

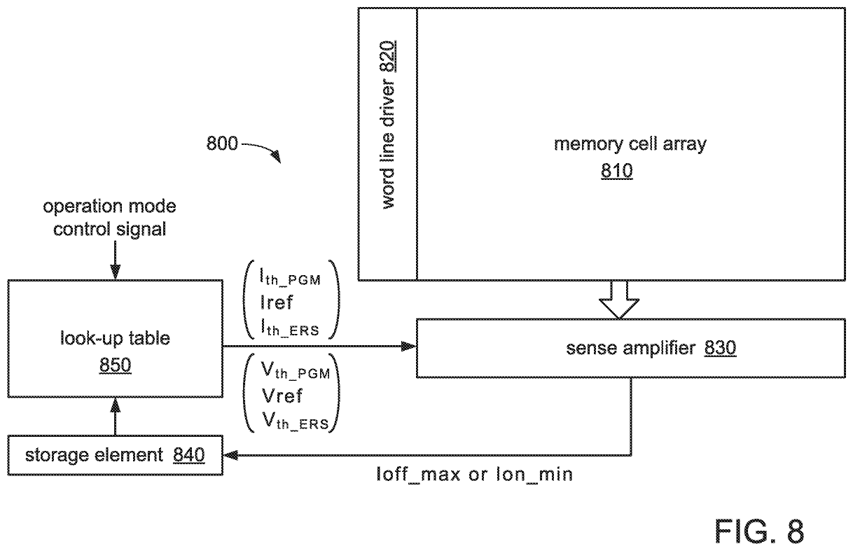

FIG. 7A is a flowchart illustrating a testing method of a MTP non-volatile memory according to a second embodiment of the present invention. FIG. 7B is a lookup table about several test criterion sets. FIG. 7C is schematically illustrates the relationships between the read current distribution curves of the MTP non-volatile memory and associated currents of the specified test criterion set of the look-up table. After the memory die is fabricated, it is necessary to perform plural testing processes for testing all memory cells.

Firstly, a program action is performed on the memory die (Step S610). In this embodiment, the program action is performed on all memory cells, or the program action containing the program verification action is performed on all memory cells.

Optionally, a soft erase action is performed on the memory die (Step S612), and a stress is applied to the memory die (Step S614). After the program action is completed, all memory dies are in the program state. Consequently, the steps S612 and S614 optionally performed. That is, in some embodiments, the soft erase action is not performed or the stress is not provided to the memory die. The stress is a column stress or a heat stress.

Then, a read action is performed on all memory cells of the memory die, and a minimum on current is acquired from all on currents (Step S616). For performing the read action, a normal read voltage (e.g., 2.5V) is provided to all memory cells. Consequently, all memory cells generate the corresponding on currents Ion. Then, the minimum on current is acquired from all on currents.

Then, a specified test criterion set is selected from plural test criterion sets according to the minimum on current, and the memory die is tested according to an erase state judgment current, a reference current and a program state judgment current of the specified test criterion set (Step S618). The erase state judgment current, the reference current and the program state judgment current may be considered as test currents for testing the memory die.

As shown in FIG. 7B, the look-up table contains 8 test criterion sets A˜H. Each of the test criterion sets A˜H contains an erase state judgment current I_{th_ERS}, a reference current Iref and a program state judgment current I_{th_PGM}.

As shown in FIG. 7C, the minimum on current Ion)min is 14.2 μA. According to the look-up table, the program state judgment current I_{th_PGM} higher than the minimum on current and the closest to the maximum off current is 14 μA.

Since the program state judgment current I_{th_PGM} of 14 μA is included in the test criterion set D, the test criterion set D is the specified test criterion set. Then, the memory die is tested according to the program state judgment current I_{th)PGM} (14 μA), the reference current Iref (7 μA) and the erase state judgment current I_{th_ERS} (4 μA) of the test criterion set D. The process of testing the memory die is similar to that of the first embodiment, and is not redundantly described herein.

Moreover, in case that the read voltage provided to the control line CL of the MTP non-volatile memory as shown in FIG. 2 is changed, the magnitude of the read current is correspondingly changed. Consequently, the step S516 of performing the read action in the first embodiment and the step S616 of performing the read action in the third embodiment may be applied to the MTP non-volatile memory as shown in FIG. 2.

For example, the control line CL of the memory cell can receive three read voltages, including a first read voltage, a normal read voltage and a second read voltage. The magnitude of the first voltage is lower than the magnitude of the normal read voltage, and the magnitude of the normal read voltage is lower than the magnitude of the second read voltage. For example, the first read voltage is 1.7V, the normal read voltage is 2.4V, and the second read voltage is 4.4V.

When the step S516 of the first embodiment is performed, the lower first read voltage is provided to the control line CL of the memory cell and the read action is performed. In comparison with the normal read voltage, the off current of the memory cell is increased. After the maximum off current Ioff_max is acquired, the subsequent step S518 is performed.

When the step S616 of the third embodiment is performed, the higher second read voltage is provided to the control line CL of the memory cell and the read action is performed. In comparison with the normal read voltage, the on current of the memory cell is decreased. After the minimum on current Ion_min is acquired, the subsequent step S618 is performed.

It is noted that numerous modifications and alterations may be made while retaining the teachings of the invention. For example, the step S618 of FIG. 7A may be modified. Consequently, the testing method of the fourth embodiment is provided. For example, a specified test criterion set is selected according to the minimum on current, and the memory die is tested according to an erase state judgment voltage, a reference voltage and a program state judgment voltage of the specified test criterion set. The operations of the fourth embodiment are similar to those of the third embodiment, and are not redundantly described herein.

FIG. 8 schematically illustrates the architecture of a non-volatile memory die using the testing method of the present invention. The non-volatile memory die 800 comprises a memory cell array 810, a word line driver 820, a sense amplifier 830, a storage element 840 and a look-up table 850.

While the read action is performed, the word line driver 820 selects a row of memory cells of the memory cell array 810. Moreover, the sense amplifier 830 receives the read currents from the row of memory cells. After the word line driver 820 selects all rows of the memory cell array 810 sequentially, the sense amplifier 830 acquires the read currents of all memory cells. Then, the sense amplifier 830 generates the maximum off current Ioff_max or the minimum on current Ion_min according to the practical requirements. Moreover, the maximum off current Ioff_max or the minimum on current Ion_min is stored in the storage element 840.

In an embodiment, the storage element 840 is an antifuse memory, a fuse memory or a non-volatile memory block of the memory cell array 810.

While the testing process is performed, the maximum off current Ioff_max or the minimum on current Ion_min is transmitted from the storage element 840 to the look-up table 850. Moreover, according to an operation mode control signal and the maximum off current Ioff_max or the minimum on current Ion_min, a specified test criterion set is selected from plural test criterion sets stored in the look-up table 850 of the memory die 800. The specified test criterion set is transmitted to the sense amplifier 830. Consequently, all memory cells of the memory cell array 810 are tested according to the specified test criterion set. The specified test criterion set contains an erase state judgment current I_{th_ERS}, a reference current Iref and a program state judgment current I_{th_PGM}, or the specified test criterion set contains an erase state judgment voltage V_{th_ERS}, a reference voltage Vref and a program state judgment voltage V_{th_PGM}.

From the above descriptions, the present invention provides a non-volatile memory and a testing method of the non-volatile memory.

During the testing process, the memory die is tested according to the erase state judgment current (or the erase state judgment current), a reference current (or the reference voltage) and the program state judgment current (or the program state judgment voltage). Moreover, the testing method of the present invention can effectively increase the yield of the memory die.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A testing method for testing a memory die of a non-volatile memory, the testing method comprising steps of:
performing an erase action on plural memory cells of the memory die;
applying a stress to the plural memory cells of the memory die;
performing a read action on the plural memory cells of the memory die to have the plural memory cells generate plural off currents, and acquiring a maximum off current from the plural off currents; and
selecting a specified test criterion set from plural test criterion sets according to the maximum off current, and testing the memory die according to plural test currents or plural test voltages of the specified test criterion set.

2. The testing method as claimed in claim 1, wherein the plural test currents of the specified test criterion set contain an erase state judgment current, a reference current and a program state judgment current.

3. The testing method as claimed in claim 2, further comprising:
performing a program action, so that the memory cells in a first portion of the memory die are in a program state;
performing the read action on the memory cells in the first portion of the memory die; and
if an on current generated by any of the memory cells in the first portion of the memory die is lower than the program state judgment current, determining the memory die as a bad die.

4. The testing method as claimed in claim 2, further comprising:
performing the erase action, so that the memory cells in a second portion of the memory die are in an erase state;
performing the read action on the memory cells in the second portion of the memory die; and
if the off current generated by any of the memory cells in the second portion of the memory die is higher than the erase state judgment current, determining the memory die as a bad die.

5. The testing method as claimed in claim 1, wherein the plural test currents of the specified test criterion set contain an erase state judgment voltage, a reference voltage and a program state judgment voltage.

6. The testing method as claimed in claim 1, wherein the erase action further contains an erase verification action.

7. The testing method as claimed in claim 1, further comprising a step of performing a soft program action after the erase action on the plural memory cells is completed.

8. The testing method as claimed in claim 1, wherein the stress is a column stress, wherein while the column stress is applied, a voltage stress is provided to the plural memory cells within a first time period.

9. The testing method as claimed in claim 1, wherein the stress is a heat stress, wherein while the heat stress is applied, a high temperature environment is provided to the plural memory cells within a second time period.

10. A testing method for testing a memory die of a non-volatile memory, the testing method comprising steps of:
performing a program action on plural memory cells of the memory die;
performing a read action on the plural memory cells of the memory die to have the plural memory cells generate plural on currents, and acquiring a minimum on current from the plural on currents; and
selecting a specified test criterion set from plural test criterion sets according to the minimum on current, and testing the memory die according to plural test currents or plural test voltages of the specified test criterion set.

11. The testing method as claimed in claim 10, wherein the plural test currents of the specified test criterion set contain an erase state judgment current, a reference current and a program state judgment current.

12. The testing method as claimed in claim 11, further comprising:
performing the program action, so that the memory cells in a first portion of the memory die are in a program state;
performing the read action on the memory cells in the first portion of the memory die; and
if the on current generated by any of the memory cells in the first portion of the memory die is lower than the program state judgment current, determining the memory die as a bad die.

13. The testing method as claimed in claim 11, further comprising:
performing an erase action, so that the memory cells in a second portion of the memory die are in an erase state;
performing the read action on the memory cells in the second portion of the memory die; and
if an off current generated by any of the memory cells in the second portion of the memory die is higher than the erase state judgment current, determining the memory die as a bad die.

14. The testing method as claimed in claim 10, wherein the plural test currents of the specified test criterion set contain an erase state judgment voltage, a reference voltage and a program state judgment voltage.

15. The testing method as claimed in claim 10, wherein the program action further contains an program verification action.

16. The testing method as claimed in claim 10, further comprising a step of performing a soft erase action after the program action on the plural memory cells is completed.

17. The testing method as claimed in claim 10, further comprising a step of applying a stress to the plural memory cells of the memory die after the program action on the plural memory cells is completed.

18. A non-volatile memory die, comprising:
a word line driver;
a memory cell array connected with the word line driver, and comprising plural memory cells;
a sense amplifier connected with the memory cell array, wherein when a read action is performed and plural read currents are generated by the plural memory cells, the sense amplifier determines a maximum off current or a minimum on current from the plural read currents;
a storage element connected with the sense amplifier, wherein the maximum off current or the minimum on current is stored in the storage element; and
a look-up table for storing plural test criterion sets, wherein when a testing process is performed, the maximum off current or the minimum on current is transmitted from the storage element to the look-up table, and a specified test criterion set is selected from the plural test criterion set according to an operation mode control signal, wherein plural test current or plural test voltages of the specified test criterion set are transmitted from the look-up table to the sense amplified, and the plural memory cells of the memory cell array are tested according to the plural test current or plural test voltages of the specified test criterion set.

19. The non-volatile memory die as claimed in claim 18, wherein the plural test currents of the specified test criterion set contain an erase state judgment current, a reference current and a program state judgment current.

20. The non-volatile memory die as claimed in claim 19, wherein after a program action is performed and the memory cells in a first portion of the non-volatile memory die are in a program state, the read action is performed on the memory cells in the first portion of the non-volatile memory die, wherein if an on current generated by any of the memory cells in the first portion of the non-volatile memory die is lower than the program state judgment current, the non-volatile memory die as a bad die.

21. The non-volatile memory die as claimed in claim 19, wherein after an erase action is performed and the memory cells in a second portion of the non-volatile memory die are in an erase state, the read action is performed on the memory cells in the second portion of the non-volatile memory die, wherein if an off current generated by any of the memory cells in the second portion of the non-volatile memory die is higher than the erase state judgment current, the non-volatile memory die is determined as a bad die.

22. The non-volatile memory die as claimed in claim 18, wherein the plural test currents of the specified test criterion set contain an erase state judgment voltage, a reference voltage and a program state judgment voltage.
